(19) United States
(12) Patent Application Publication
(10) Pub. No.: US 2023/0187169 A1
(43) Pub. Date: Jun. 15, 2023

(54) METHOD TO MEASURE RADICAL ION FLUX USING A MODIFIED PIRANI VACUUM GAUGE ARCHITECTURE

(71) Applicant: Applied Materials, Inc, Santa Clara, CA (US)

(72) Inventors: Martin Hilkene, Gilroy, CA (US); Samuel Howells, Portland, OR (US)

(21) Appl. No.: 17/549,703

(22) Filed: Dec. 13, 2021

(51) Int. Cl. H01J 37/244; H01J 37/32; G01L 21/12

(52) U.S. Cl. CPC H01J 37/244; H01J 37/32834; H01J 37/32357; G01L 21/12

(57) ABSTRACT

Embodiments disclosed herein include, a sensor for detecting radical ion flux. In an embodiment, the sensor comprises a first resistor, where the first resistor comprises a length of wire of a first catalytic composition. In an embodiment, a second resistor is electrically coupled to the first resistor, where the second resistor comprises a length of wire of the first catalytic composition. In an embodiment, the second resistor is coated with a non-catalytic material. In an embodiment, the sensor further comprises a third resistor electrically coupled to the second resistor, and a fourth resistor electrically coupled to the first resistor and the third resistor

### BACKGROUND

### 1) Field

Embodiments relate to the field of semiconductor manufacturing and, in particular, to a method and apparatus for measuring radical ion fluxes with a Pirani vacuum gauge.

### 2) Description of Related Art

Radical ion fluxes in plasma processing chamber are responsible for much of the physical changes to the substrate within the plasma processing chamber. However, there are currently no cost effective sensors that are available to detect radical ion flux in remote plasma tools or in-situ based plasma processing chambers. Without the ability to measure radical ion fluxes, it becomes difficult to implemented health checks of the plasma source, detect process drifts, or implement process optimization.

### SUMMARY

Embodiments disclosed herein include, a sensor for detecting radical ion flux. In an embodiment, the sensor comprises a first resistor, where the first resistor comprises a length of wire of a first catalytic composition. In an embodiment, a second resistor is electrically coupled to the first resistor, where the second resistor comprises a length of wire of the first catalytic composition. In an embodiment, the second resistor is coated with a non-catalytic material. In an embodiment, the sensor further comprises a third resistor electrically coupled to the second resistor, and a fourth resistor electrically coupled to the first resistor and the third resistor.

Embodiments may further comprise plasma processing tool. In an embodiment, the plasma processing tool comprises a chamber, and a sensor in the chamber. In an embodiment, the sensor comprises a first catalytic wire and a second catalytic wire, where the second catalytic wire is covered by a non-catalytic material.

Embodiments may further comprise a plasma processing tool. In an embodiment, the plasma processing tool comprises a remote plasma source, and a chamber, where the chamber is fluidically coupled to the remote plasma source. In an embodiment, the tool further comprises a support in the chamber for securing a substrate, an exhaust fluidically coupled to the chamber, and a first radical ion sensor in the chamber. In an embodiment, a second radical ion sensor is in the remote plasma source, and a third radical ion sensor is in the exhaust.

### BRIEF DESCRIPTION OF THE DRAWINGS

FIG. 1 is a schematic illustration of a sensor for detecting radical ion fluxes, in accordance with an embodiment.

FIG. 2 is a graph of the resistances versus temperature of a platinum wire, in accordance with an embodiment.

FIG. 3 is a graph of the temperature of a wire in a plasma chamber over the course of various plasma settings, in accordance with an embodiment.

FIG. 4A is a plan view illustration of a substrate with a radical ion flux sensor at each quadrant and a center of the substrate, in accordance with an embodiment.

FIG. 4B is a plan view illustration of a substrate with a plurality of radical ion flux sensors across a surface of the substrate, in accordance with an embodiment.

FIG. 4C is a plan view illustration of a substrate with a plurality of radical ion flux sensors in a line pattern across the surface of the substrate, in accordance with an embodiment.

FIG. 5 is a perspective view illustration of a processing chamber with a radical ion flux sensor at the end of a probe that extends over a substrate in the chamber, in accordance with an embodiment.

FIG. 6A is a cross-sectional illustration of a plasma processing chamber with a radial ion flux sensor in the main chamber and along an exhaust line, in accordance with an embodiment.

FIG. 6B is a cross-sectional illustration of a plasma processing chamber with a remote plasma source and a plurality of radical ion flux sensors, in accordance with an embodiment.

FIG. 7 illustrates a block diagram of an exemplary computer system that may be used in conjunction with a processing tool, in accordance with an embodiment.

### DETAILED DESCRIPTION

Systems described herein include a method and apparatus for measuring radical ion fluxes with a device based on a Pirani vacuum gauge. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, there is currently a lack of cost effective sensors for measuring radical ion fluxes in plasma processing chambers. Accordingly, embodiments disclosed herein include sensors that can be easily integrated into plasma processing chambers or provided on substrates that are inserted into the processing chambers. In a particular embodiment, the sensors may be modified Pirani vacuum gauge sensors. For example, the sensors may include a first wire and a second wire. The first wire is exposed and the second wire is surrounded by an insulating layer. In an embodiment, the first wire and the second wire may be catalytic material, such as platinum or nickel. Since the first wire is exposed, the catalytic material promotes the recombination of radical ions, which leads to a temperature change in the first wire. The temperature change corresponds to an increase in the resistance of the first wire, and the resistance change can be directly measured. Since the second wire is covered by a non-catalytic material, the second wire can serve as a reference. Furthermore, it is to be appreciated that the dimensions (e.g., surface area, length, mass) of the second wire is substantially equal to the dimensions of the first wire. As such, the difference between the temperature of the first wire and the temperature of the second wire can be correlated to a radical ion flux within the chamber.

In an embodiment, the sensor is provided on a substrate that is inserted into the plasma chamber. For example, a plurality of sensors can be fabricated on a substrate to provide spatial resolution of the radical ion flux within the plasma chamber. In an embodiment, sensors may be extended over substrates with a probe architecture. Additionally, sensors may be provided throughout different portions of the plasma chamber. For example, a sensor may be located downstream in an exhaust line of the chamber, in a remote plasma chamber, or adjacent to an exit (e.g., the process chamber side of a remote plasma chamber/source).

In an embodiment, the use of radical ion flux sensors allows for several benefits in chamber monitoring. In some embodiments, such sensors can be used as part of a health-check solution of plasma sources (e.g., either remote or in-situ). In other embodiments, such sensors can be used to help with process drift detection. Other embodiments may use the sensors to implement process optimization.

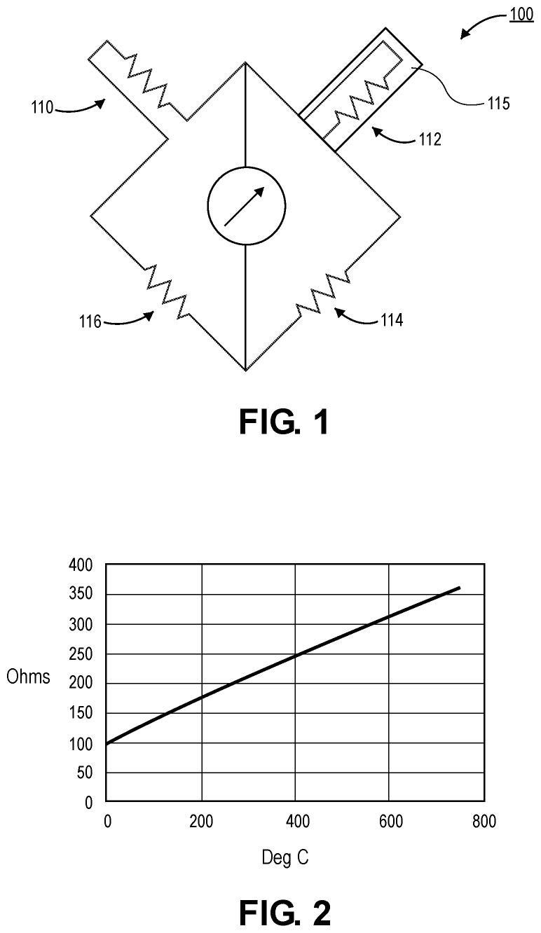

Referring now to FIG. 1, a schematic illustration of a sensor 100 is shown, in accordance with an embodiment. In an embodiment, the sensor 100 comprises a Wheatstone bridge architecture. That is a set of four resistors 110, 112, 114, and 116 may be electrically coupled to each other in a ring architecture. In an embodiment, the first resistor 110 and the second resistor 112 may be formed by catalytic wires. For example, the catalytic wires may be a material that aids in the recombination of the radical ions. For example, in the case of hydrogen and oxygen radical ions, the first catalytic wires may include platinum or nickel. Of course, plasmas with different species may include other types of catalytic wires.

In an embodiment, the first resistor 110 and the second resistor 112 may be substantially the same as each other. The difference between the first resistor 110 and the second resistor 112 is that the second resistor 112 is covered by a non-catalytic material 115. For example, the second resistor 112 may be coated with a material 115 comprising silicon and oxygen (e.g., SiO₂) or aluminum and oxygen (e.g., Al₂O₃). In an embodiment, the coating 115 is deposited over the second resistor 112 with any suitable deposition process. In a particular embodiment, the coating 115 is provided over the second resistor 112 with an atomic layer deposition (ALD) process. In an embodiment, the ALD coating may cover all wetted parts except for the catalytic platinum/nickel resistor component of the first resistor 110. This will minimize reaction of the passive components as well as the reference platinum/nickel sensor of the second resistor 112. To manufacture such a structure, all wetted components may be coated with the ALD process, and the film may be etched of the catalytic platinum/nickel first resistor 110.

In an embodiment, the catalytic wires are heated to a temperature. The voltage required to do this is monitored using the Wheatstone bridge architecture. Changes in the voltage correlate to the temperature change of the catalytic wires induced by radical ion recombination.

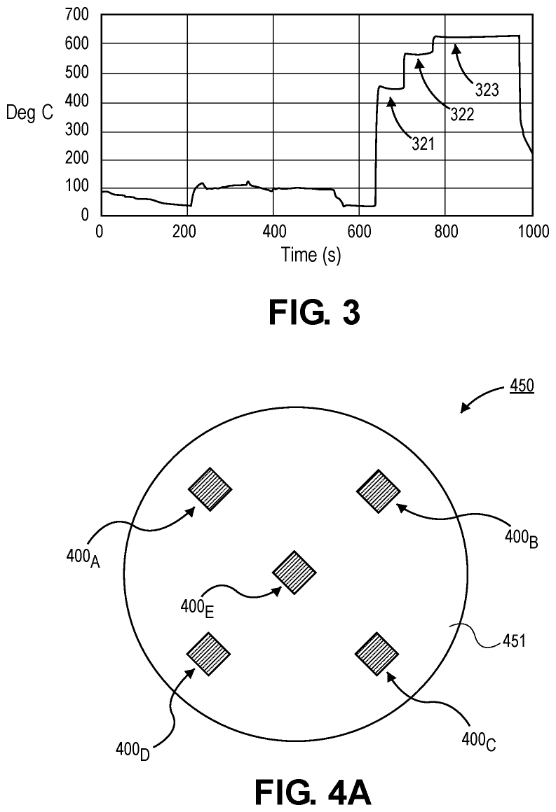

Referring now to FIG. 2, a graph of the temperature versus resistance of the catalytic wire is shown, in accordance with an embodiment. As shown, there is a linear relationship between the temperature and the resistance. As such, changes in resistance can be measured in order to detect a change in temperature. In the illustrated embodiment, the catalytic material being graphed is platinum. However, it is to be appreciated that relationships between temperature and resistance may also be provided when other catalytic material is used, such as nickel. Whereas platinum has a linear relationship, nickel may have a non-linear relationship which may require the application of a calibration curve to such an embodiment.

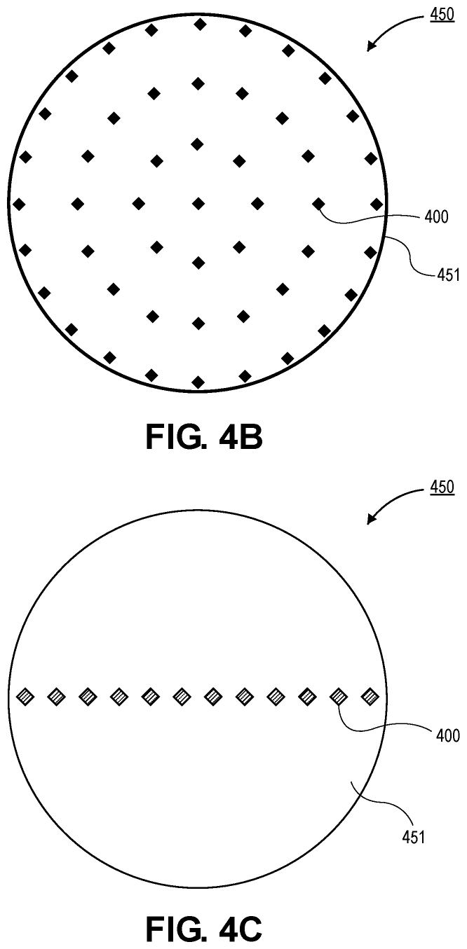

Referring now to FIG. 3, a graph of the temperature of the first catalytic wire 110 over time is shown, in accordance with an embodiment. Up until approximately 625 seconds, the plasma is only an argon plasma. As such, there is no heating due to radical ion recombination. For example, the temperature of the first catalytic wire 110 may be at approximately 100° C. At approximately 625 seconds processing gasses, such as oxygen and hydrogen may be added to the chamber. The processing gasses are ionized to form radical ion species. As shown at a first step 321, the temperature of the first catalytic wire 110 increases. A power increase from 1 KW at the first step 321 to 2 KW at the second step 322 results in an increase in the temperature. Further, an increase to 3 KW at the third step 323 results in yet another increase in the temperature. As such, changes to the temperature of the catalytic wire 110 can be correlated to changes in the radical ion flux. In an embodiment, the catalytic wire 110 is configured to provide rapid changes in the temperature. This is enabled by having a wire with a low mass. As such, rapid detection of changes to the radical ion flux are possible.

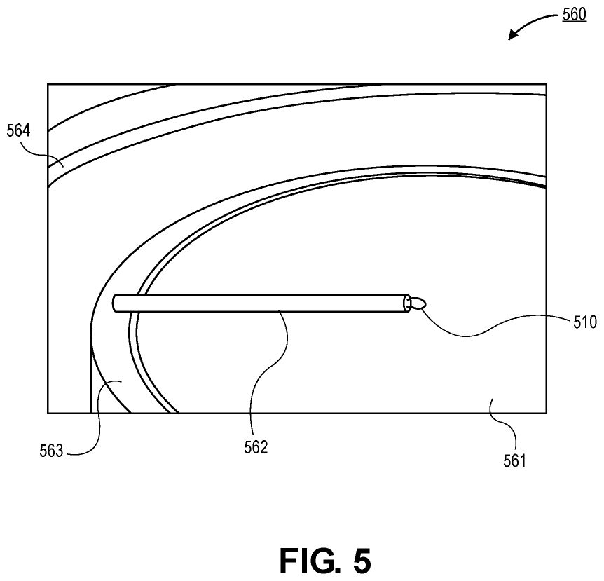

Referring now to FIGS. 4A-4C, a series of plan view illustrations depicting various architectures that utilize radical ion flux sensors is shown, in accordance with different embodiments. In an embodiment, the sensors are provided on a substrate. The substrate may be a semiconductor substrate, such as a silicon substrate. In other embodiments, the substrate may be glass or any other type of substrate common to semiconductor manufacturing processes.

Referring now to FIG. 4A, a plan view illustration of a sensor device 450 is shown, in accordance with an embodiment. In an embodiment, the sensor device 450 comprises a plurality of radical ion flux sensors 400A-400E that are dispersed over a surface of the substrate 451. For example, sensors 400A-400D may each be in a different quadrant of the substrate 451, and sensor 400E may be at a center of the substrate 451. As such, radical ion flux readings may be provided for a plurality of different locations within the chamber.

In an embodiment, electrical circuitry for the sensors 400A-400E may be fabricated as part of the substrate 451. In other embodiments, the sensors 400A-400E may be discrete sensors that are mounted to the substrate 451. In some embodiments, data from the sensors 400A-400E may be stored in memory fabricated on or attached to the substrate 451. Alternatively, connections from the substrate to devices external to the processing chamber may be made through a vacuum feedthrough, or through a thin tape layer that passes over an O-ring of the chamber.

In an embodiment, each sensor 400A-400E may include an exposed first catalytic wire and a second catalytic wire that is coated with a non-catalytic material. That is, each sensor may include a wire for sensing the radical ion flux, and a wire for serving as a temperature reference. In such embodiments, the first catalytic wires and the second catalytic wires have a one-to-one ratio. In other embodiments, each sensor 400A-400E may include a first catalytic wire, and each sensor 400A-400E may not include a second coated catalytic wire. That is, the first catalytic wires and the second coated wires may not have a one-to-one ratio in some embodiments.

Referring now to FIG. 4B, a plan view illustration of a sensor device 450 is shown, in accordance with an additional embodiment. As shown, a plurality of sensors 400 are arranged across a surface of a substrate 451. Such an embodiment may be referred to as a contour sensor 400 layout. In the illustrated embodiment, forty-nine sensors 400 are used. However, it is to be appreciated that any number of sensors 400 may be used in order to provide a desired level of resolution.

In an embodiment, each of the sensors 400 may include a first catalytic wire that is exposed and a second catalytic wire that is covered with a coating. Such embodiments may be referred to as a one-to-one architecture. In other embodiments, each sensor 400 may include a first catalytic wire that is exposed, and fewer than all sensors 400 may have a reference wire (i.e., a coated catalytic wire). In such an embodiment, the first catalytic wires may have a many-to-one ratio with the coated second catalytic wires.

Similar to the embodiment described with respect to FIG. 4A, the electronics to operate and store data from the sensors 400 may be on board the substrate 451. In other embodiments, wires may pass through vacuum feedthroughs or across O-rings. The sensors 400 may be discrete structures that are attached to the substrate 451. In other embodiments, the sensors 400 may be integrated as part of the substrate 451.

Referring now to FIG. 4C, a plan view illustration of a sensor device 450 is shown, in accordance with an additional embodiment. As shown, a plurality of sensors 400 are arranged in a line across a surface of a substrate 451. Such an embodiment may be referred to as a line scan layout. In the illustrated embodiment, eleven sensors 400 are used. However, it is to be appreciated that any number of sensors 400 may be used in order to provide a desired level of resolution.

In an embodiment, each of the sensors 400 may include a first catalytic wire that is exposed and a second catalytic wire that is covered with a coating. Such embodiments may be referred to as a one-to-one architecture. In other embodiments, each sensor 400 may include a first catalytic wire that is exposed, and fewer than all sensors 400 may have a reference wire (i.e., a coated catalytic wire). In such an embodiment, the first catalytic wires may have a many-to-one ratio with the coated second catalytic wires.

Similar to the embodiment described with respect to FIG. 4A, the electronics to operate and store data from the sensors 400 may be on board the substrate 451. In other embodiments, wires may pass through vacuum feedthroughs or across O-rings. The sensors 400 may be discrete structures that are attached to the substrate 451. In other embodiments, the sensors 400 may be integrated as part of the substrate 451.

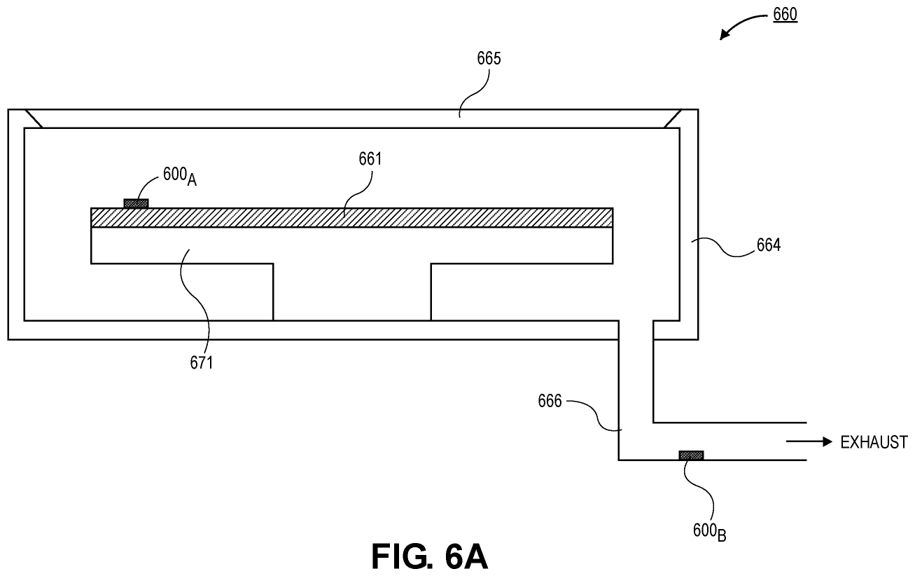

Referring now to FIG. 5, a perspective view illustration of a portion of a plasma chamber 560 is shown, in accordance with an embodiment. In an embodiment, a substrate 561 is supported in the chamber 560. For example, the substrate 561 may be a semiconductor substrate, such as a silicon wafer. An edge ring 563 may surround a perimeter of the substrate 561. A chamber wall 564 may surround a perimeter of the edge ring 563.

In an embodiment, a probe 562 may be attached to the edge ring 563 and extend out over a surface of the substrate 561. At an end of the probe 562 over the substrate 561, a catalytic wire 510 may be provided. The catalytic wire 510 may be a platinum wire or a nickel wire in some embodiments. In an embodiment, the probe 562 may further comprise a second catalytic wire (not shown) that is coated with a non-catalytic layer, such as SiO₂ or Al₂O₃. The coated second catalytic wire may alternatively be provided on a different probe (not shown in FIG. 5). While shown as extending over the surface of the substrate 561, it is to be appreciated that the probe 562 may not extend over surfaces of the substrate 561 during processing, as this may result in shadowing and add potential for metal contamination. Instead, the probe 562 may be placed on edge ring 563. Additionally, it is to be appreciated that there could also be multiple sensors around the edge ring 563.

In an embodiment, the probe 562 may be coupled to an external computing system that stores data and controls the sensor. One or more wires at the end of probe attached to the edge ring 563 may pass through a vacuum feedthrough through the chamber wall 564 or pass over an O-ring (not shown) between a chamber lid (not shown) and the chamber wall 564.

In the illustrated embodiment, a single probe 562 is shown for simplicity. However, it is to be appreciated that any number of probes 562 may be used to provide a desired spatial resolution of the radical ion flux. In yet another embodiment, the probe 562 may be scanned over the surface of the substrate 561 in order to provide a spatial chart of the radical ion flux for a given plasma process. For example, the probe 562 may be a telescoping probe and be able to scan back and forth across the substrate 561 in a windshield wiper like pattern. Additionally, the probe 562 may scan in a linear fashion across the substrate 561 and/or chamber 560.

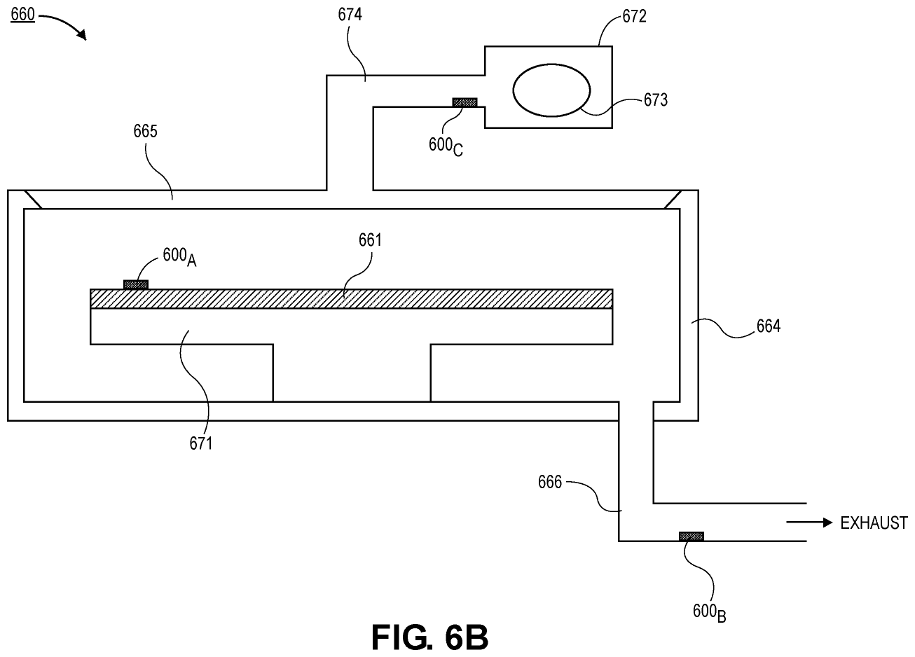

Referring now to FIGS. 6A and 6B, cross-sectional illustrations of plasma processing tools are shown, in accordance with various embodiments. The plasma processing tool 660 may be used to implement one or more plasma processes on a substrate 661 held in the chamber 664.

Referring now to FIG. 6A, a cross-sectional illustration of a plasma processing tool 660 is shown, in accordance with an embodiment. In an embodiment, the plasma processing tool 660 comprises a chamber 664 with a lid 665. Processing gasses may be flown into the chamber 664 (e.g., through the lid 665), and a plasma may be struck within the chamber 664 between the lid 665 and a substrate 661. In an embodiment, the substrate 661 may be a wafer, such as a silicon wafer or any semiconductor substrate. In an embodiment, the substrate 661 may be supported by a pedestal 671. The pedestal 671 may be a temperature controlled component that secures the substrate 661 (e.g., with a vacuum chucking process, an electrostatic chucking process, or the like).

In an embodiment, the chamber 664 may be held at a vacuum pressure (e.g., below atmospheric pressure) through the aid of an exhaust system 666. The exhaust system 666 may include one or more pumps (not shown) that are configured to lower the pressure inside the chamber 664.

In an embodiment, a plurality of sensors 600 may be provided within the plasma processing tool 660. In the embodiment shown in FIG. 6A, a first sensor 600A is provided over a surface of the substrate 661. The sensor 600A may comprise a first catalytic wire and a second catalytic wire that is covered with a non-catalytic coating. In an embodiment, the sensor 600A may be one of many sensors that are provided over the substrate 661. For example, sensors 600 may be provided over each quadrant of the substrate 661 (similar to the embodiment shown in FIG. 4A), sensors 600 may be provided as a contour map architecture (similar to the embodiment shown in FIG. 4B), or sensors 600 may be provided in a line pattern (similar to the embodiment shown in FIG. 4C). In other embodiments, the sensor 600A may be provided above the substrate 661. For example, a probe (not shown) may extend over the top surface of the substrate 661, and the sensor 600A may be at the end of the probe. Though, it is to be appreciated that the sensor 600A may only be above the substrate holder during set-up and/or health checks, and may be removed from over the substrate 661 during processing of the substrate 661.

In an embodiment, a second sensor 600B may be provided along the exhaust line 666. The second sensor 600B may include a first catalytic wire and a second catalytic wire that is coated with a non-catalytic coating. For example, the second sensor 600B may include a sensor architecture that is similar to what is shown in FIG. 1. As such, the radical ion flux can be measured at a location downstream from the chamber 664.

Referring now to FIG. 6B, a cross-sectional illustration of a plasma processing tool 660 is shown, in accordance with an additional embodiment. In an embodiment, the plasma processing tool 660 comprises a chamber 664 with a lid 665. In an embodiment, a remote plasma source 672 is coupled to the chamber 664. The plasma 673 may be generated in the remote plasma source 672 and flow through pipe 674 to the lid 665. The plasma 673 may disperse through the lid 665 (which may be a baffle in some embodiments) into the chamber 664.

In an embodiment, a substrate 661 may be supported by a pedestal 671. The pedestal 671 may be a temperature controlled component that secures the substrate 661 (e.g., with a vacuum chucking process, an electrostatic chucking process, or the like). In an embodiment, the substrate 661 may be a wafer, such as a silicon wafer or any semiconductor substrate.

In an embodiment, the chamber 664 may be held at a vacuum pressure (e.g., below atmospheric pressure) through the aid of an exhaust system 666. The exhaust system 666 may include one or more pumps (not shown) that are configured to lower the pressure inside the chamber 664.

In an embodiment, a plurality of sensors 600 are provided in the plasma processing tool 660. In the embodiment shown in FIG. 6B, a first sensor 600A is provided over a surface of the substrate 661. The sensor 600A may comprise a first catalytic wire and a second catalytic wire that is covered with a non-catalytic coating. In an embodiment, the sensor 600A may be one of many sensors that are provided over the substrate 661. For example, sensors 600 may be provided over each quadrant of the substrate 661 (similar to the embodiment shown in FIG. 4A), sensors 600 may be provided as a contour map architecture (similar to the embodiment shown in FIG. 4B), or sensors 600 may be provided in a line pattern (similar to the embodiment shown in FIG. 4C). In other embodiments, the sensor 600A may be provided above the substrate 661. For example, a probe (not shown) may extend over the top surface of the substrate 661, and the sensor 600A may be at the end of the probe.

In an embodiment, a second sensor 600B may be provided along the exhaust line 666. The second sensor 600B may include a first catalytic wire and a second catalytic wire that is coated with a non-catalytic coating. For example, the second sensor 600B may include a sensor architecture that is similar to what is shown in FIG. 1. As such, the radical ion flux can be measured at a location downstream from the chamber 664.

In an embodiment, a third sensor 600c may be provided between the remote plasma source 672 and the lid 665. For example, the third sensor 600c may be provided along the pipe 674. In other embodiments, the third sensor 600c may be provided within the remote plasma source 672. The inclusion of a third sensor 600c allows for radical ion fluxes to be read upstream and downstream of the chamber 664.

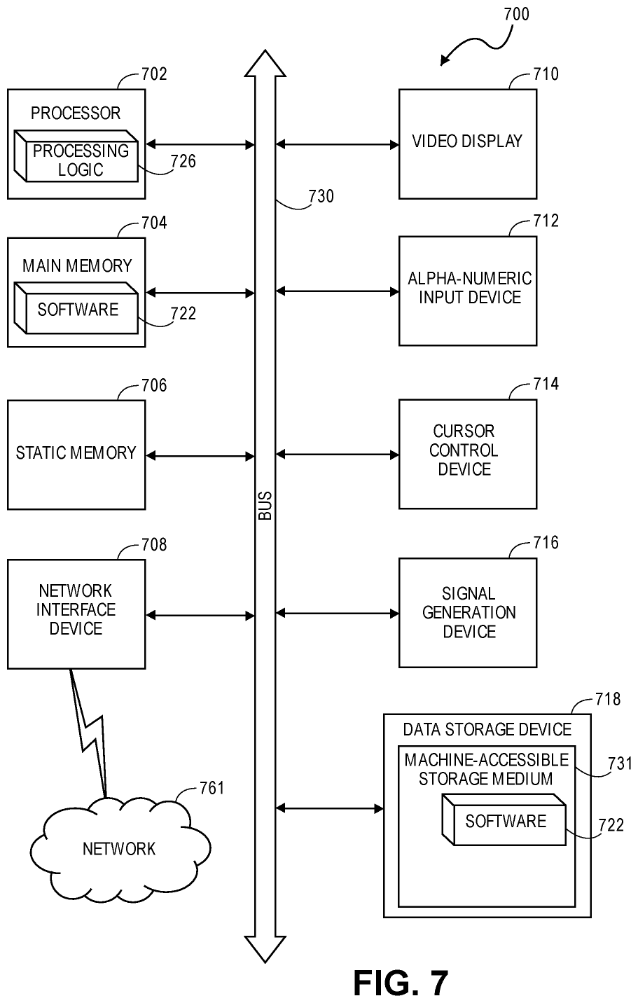

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 720 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

1.-20. (canceled)

21. A sensor for detecting radical flux, comprising:
a first temperature sensor that comprises a first surface of a first catalytic composition; and
a second temperature sensor that comprises a surface, and wherein the second surface is coated with a non-catalytic material.

22. The sensor of claim 21, wherein the first temperature sensor and the second temperature sensor are connected to each other in a Wheatstone bridge configuration.

23. The sensor of claim 22, wherein changes to a voltage across the Wheatstone bridge correlate to a temperature change of the first temperature sensor induced by radical ion recombination.

24. The sensor of claim 21, wherein the first catalytic composition comprises platinum.

25. The sensor of claim 21, wherein the first catalytic composition comprises nickel.

26. The sensor of claim 21, wherein the non-catalytic material comprises silicon and oxygen.

27. The sensor of claim 21, wherein the non-catalytic material comprises aluminum and oxygen.

28. The sensor of claim 21, wherein the sensor is integrated onto a substrate that is insertable into a plasma chamber.

29. The sensor of claim 21, wherein the sensor is provided at an end of a probe within a plasma chamber.

30. The sensor of claim 21, wherein the first temperature sensor and the second temperature sensor are resistors or thermocouples.

31. A plasma processing tool, comprising:
a chamber; and
a sensor in the chamber, wherein the sensor comprises:
a first catalytic surface; and
a second surface, wherein the second surface is covered by a non-catalytic material.

32. The plasma processing tool of claim 31, wherein the sensor is on a probe that extends over a support for holding a substrate.

33. The plasma processing tool of claim 31, wherein the sensor is in an exhaust line coupled between the chamber and a vacuum pump.

34. The plasma processing tool of claim 31, further comprising:
a remote plasma source, wherein the sensor is located within the remote plasma source.

35. The plasma processing tool of claim 31, wherein the first catalytic surface and the second surface comprise platinum.

36. The plasma processing tool of claim 31, wherein the first catalytic surface and the second surface comprise nickel.

37. The plasma processing tool of claim 31, wherein the non-catalytic material comprises silicon and oxygen.

38. The plasma processing tool of claim 31, wherein the non-catalytic material comprises aluminum and oxygen.

39. A plasma processing tool, comprising:
a remote plasma source;
a chamber, wherein the chamber is fluidically coupled to the remote plasma source;
a support in the chamber for securing a substrate;
an exhaust fluidically coupled to the chamber;
a first radical sensor in the chamber;
a second radical sensor in the remote plasma source; and
a third radical sensor in the exhaust.

40. The plasma processing tool of claim 39, wherein the first radical sensor, the second radical sensor, and the third radical sensor comprise:
a first catalytic surface; and
a second surface, wherein the second surface is covered by a non-catalytic material.
